(19) United States
(12) Patent Application Publication
(10) Pub. No.: US 2003/0117862 A1
(43) Pub. Date: Jun. 26, 2003

(54) Method for computer assisted processing of a structure comprising a first element and a second element belonging together

(76) Inventors: Wendelin Feiten, Deutschland (DE); Wolfgang Rencken, Deutschland (DE)

Correspondence Address: STAAS & HALSEY LLP, 700 11TH STREET, NW, SUITE 500, WASHINGTON, DC, 20001, US

(21) Appl. No.: 10/182,914

(22) PCT Filed: Feb. 2, 2001
(86) PCT No.: PCT/DE01/00412

(30) Foreign Application Priority Data
Feb. 2, 2000 (EP) 10004409.3

(51) Int. Cl. G11C 7/00

(52) U.S. Cl. 365/200

(57) ABSTRACT

Computer assisted processing is performed for a structure having a first element and a second element belonging together, where a third position of the first element is determined by a first position of the first element and a changed second position of the first element. On processing, the structure at least one fourth position of the second element of the structure is altered, based on the third position of the first element.

The invention relates to computer-assisted processing of a structure comprising a first element and a second element belonging together.

Such a method is disclosed by [1].

In the method disclosed by [1] for orienting a robot in a predefined space, an electronic map of the predefined space is drawn up. By using the electronic map, the robot determines its position in the predefined space and orients itself in the predefined space.

When the electronic map is being drawn up, surrounding elements in the space are recorded by the robot by using a recording means, for example a laser scanner or a camera. The recordings are digitized and fed into a computing unit, with which the robot is equipped, so that the recordings are present in the robot as digitized images.

The surrounding elements recorded from the digitized images are idealized by means of simple geometric basic elements, for example points or lines, and are at least partly combined to form coherent structures, for example polygons.

Individual, uncombined basic elements and the coherent structures are entered into the electronic map.

In this way, the electronic map which represents the predefined space is drawn up by the robot.

By using the map, the robot orients itself in the predefined space in such a way that the robot which is located at a current position in the space records an image area in the space by using the recording means. The recording is digitized in the same way as when drawing up the electronic map, recorded surrounding elements are idealized and stored.

The robot then attempts to make the recorded image region coincide with the stored map, in order in this way to obtain information about its current position and its orientation.

When determining the coincidence, a first structure comprising at least one basic element, which characterizes the recorded image area, is compared with at least one second predefined structure comprising at least one basic element from the electronic map.

In the method disclosed by [1], the drawing up of the electronic map and the orientation of the robot take place at the same time, so that during a movement of the robot in the predefined space, an updated electronic map of the space is determined at periodic intervals.

This approach conceals in particular the disadvantage that it is not robust with respect to errors in recordings which are made by a robot for the purpose of its orientation in the predefined space which is represented by the electronic map.

If, during the processing of a structure of coherent basic elements, the robot compares the first structure from a currently recorded image section with the second structure from the electronic map, then the method disclosed by [1] is not sufficiently robust to lead to results of sufficient quality.

The invention is therefore based on the problem of specifying a method and arrangement for the computer-assisted processing of a structure of elements belonging together which is robust with respect to possible recording errors and which can be carried out more quickly and with less computing effort than the known methods.

The problem is solved by the method and the arrangement having the features according to the respective independent claim.

In the method for the computer-assisted processing of a structure comprising a first element and a second element belonging together, a third position of the first element is determined by using a first position of the first element and a changed second position of the first element. On processing the structure, at least one fourth position of the second element of the structure is changed by using the third position of the first element.

The arrangement for the computer-assisted processing of a structure comprising a first element and a second element which belong together has a processor which is set up in such a way that the following steps can be carried out,

a third position of the first element is determined by using a first position of the first element and a changed second position of the first element;

on processing the structure, at least one fourth position of the second element of the structure is changed by using the third position of the first element.

The arrangement is in particular suitable for carrying out the method according to the invention or one of its developments explained below.

Preferred developments of the invention emerge from the dependent claims.

The developments described in the further text relate both to the method and to the arrangement.

The invention and the developments described in the further text can be implemented both in software and in hardware, for example by using a specific electric circuit.

Furthermore, an implementation of the invention or a development described in the further text is possible by means of a computer readable storage medium, on which a computer program is stored which carries out the invention or development.

In addition, the invention and/or each development described in the further text can be implemented by a computer program product which has a storage medium on which a computer program is stored which carries out the invention and/or development.

In one development, an element is described by at least one point and a line of predefinable shape.

In a further refinement, a position of an element is described by the point of the element and an orientation of the line of the element.

In one development, the third position of the first element is determined by an angle between a first orientation of the first position of the first element and a second orientation of the second position of the first element being determined, the angle is averaged and a direction of the averaged angle describes a third orientation of the third position of the first element.

In one refinement, the fourth position of the second element is changed in such a way that the energy which has to be expended for a change in at least one position of the first element and one position of the second element is minimized.

The structure or the processed structure can be contained or entered in a map, which is recorded as a scene from the surroundings by using a recording means, for example an acoustic and/or an optical recording means, in particular a laser scanner and/or a camera. In this case, it is valid to compare the recorded structures with a stored structure, in order in this way to become oriented or to construct or to process a map.

In one development, the map is used for planning the travel path of a mobile autonomous device.

The invention can preferably be used for the orientation of a mobile autonomous device, for example a robot, or else for determining a map for the orientation of the mobile autonomous device. In this case, an element represents a physical object.

Furthermore, the invention can be used for monitoring and/or controlling the mobile autonomous device.

By using the map and the structure contained therein, a current position of the mobile autonomous device in the map and/or a travel path of the mobile autonomous device can be determined.

In a development, the mobile autonomous device is monitored and/or controlled by using the structure and/or the processed structure.

Exemplary embodiments of the invention are illustrated in figures and will be explained in more detail in the further text.

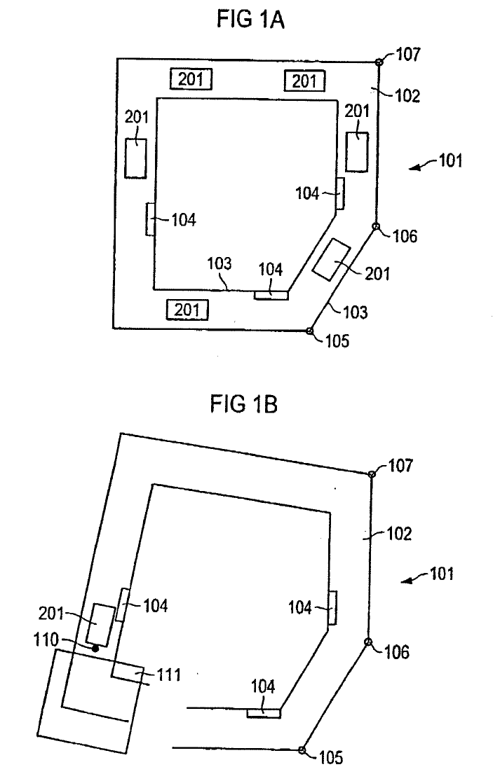

FIGS. 1a and 1b show a sketch of a gangway, in which a robot is to orient itself (FIG. 1a), and also a symbolic sketch of the recordings of the robot and its conversion into a map, an error in the determination of the map and its effects on the imaging of the gangway as compared with the actual gangway from FIG. 1a being illustrated (FIG. 1b);

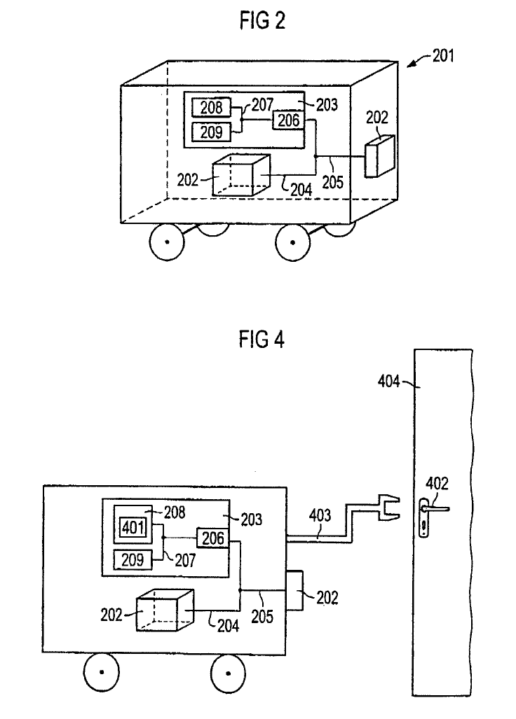

FIG. 2 shows a sketch of a robot with recording means;

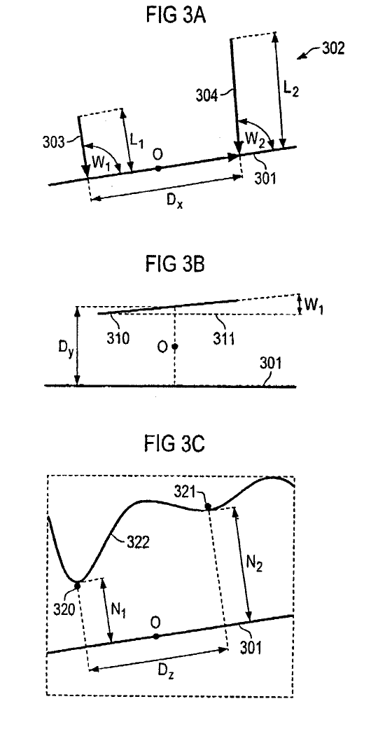

FIGS. 3a to 3c show sketches, in each case of one basic element with various surroundings information types and surroundings information features;

FIG. 4 shows a sketch in which an application of the method is illustrated in which a structure represents a model of a physical object;

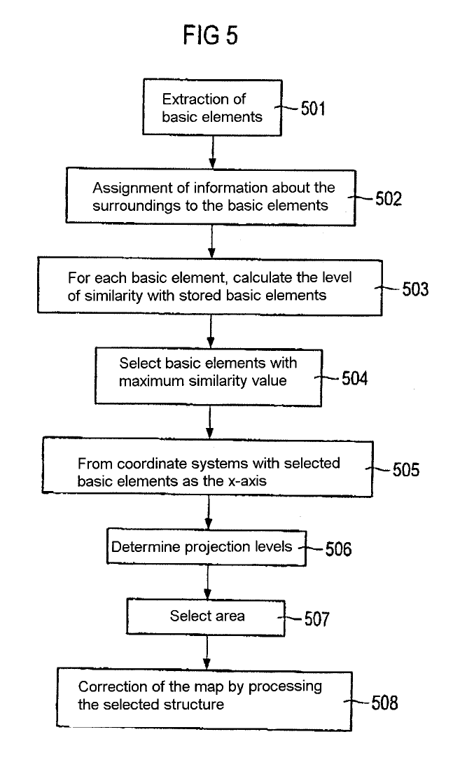

FIG. 5 shows a flowchart, in which method steps of an exemplary embodiment are illustrated;

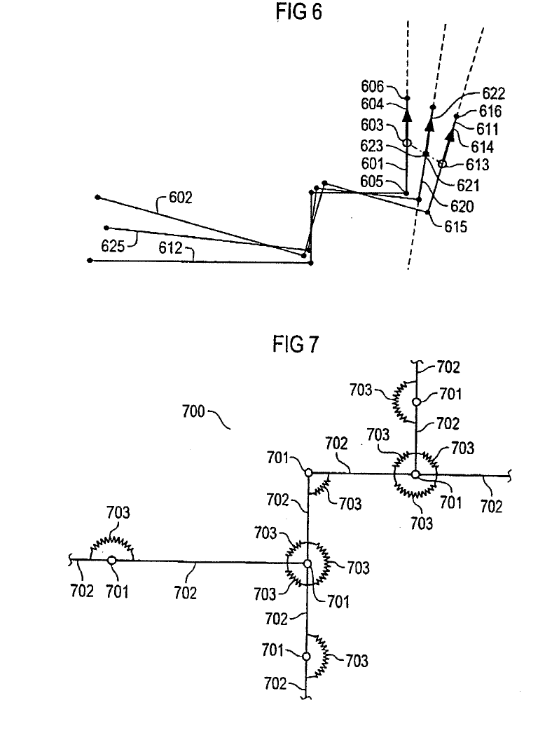

FIG. 6 shows the principle of processing a structure, a new structure with a changed position being determined;

FIG. 7 shows a framework with nodes, rods and springs.

FIG. 2 shows a robot 201 having a plurality of laser scanners 202. The laser scanners 202 record images of the surroundings of the robot 201 and feed the images to a computing unit 203 via links 204, 205.

Via an input/output interface 206, which is connected via a bus 207 to a memory 208 and a processor 209, the image signals are fed to the store 208.

The method described in the further text is carried out in the processor 209. The processor 209 is therefore set up in such a way that the method steps described in the further text can be carried out.

FIG. 1a shows in symbolic terms a map 101, which represents a gangway 102. The robot 201 moves through the gangway and records images of its surroundings with the laser scanners 202. In the process, it records walls 103. At various times, the robot 201 records images of its surroundings, as a result of which an image of the entire gangway 102 is produced.

In the gangway 102, there are also obstacles 104 in the form of racks or cabinets which project into the gangway 102.

Corners 105, 106, 107 of the gangway 102 are interpreted as the starting point or end point of a wall, which is stored in the form of a path section.

FIG. 1b represents the map from FIG. 1a it it is not the case, as assumed in the situation illustrated in FIG. 1a, that ideal recordings are made but if errors occur during the recording by the robot 201.

The robot 201 moves in the gangway 102 and records images of its surroundings at periodic intervals. On the basis of the recorded images and the stored map 101, the robot 201 orients itself.

The orientation is carried out by the robot 201 feeding the images to the processor 209. In the processor 209, a similarity comparison of elements of the recorded image with elements of the stored, predefined map 101 is carried out and an attempt is made to determine the current position of the robot 201 therefrom.

The robot 201 is located at a position 110 and records an image area 111 with its laser scanner. It attempts to bring this image area 111 into agreement with the stored map 101 and therefore to determine information for its orientation.

This corresponds to the comparison of a first structure, which characterizes the recorded image area 111, with at least one predefined second structure from the map 101.

In addition to the orientation of the robot, the structure comparison can also be used to improve an erroneous map to the effect that the improved map supplies a more accurate description of the surroundings of the robot.

For this purpose, the orientation of the robot and the improvement of the map, the following method is carried out, which is illustrated in FIG. 5.

In a first step 501, basic elements are extracted from the recorded image 111 by the processor 209.

A basic element is to be understood to mean a path with a starting point and an end point, each of which represents a wall in the gangway 102. Further basic elements are points and lines of predefinable form.

The extraction is carried out using known image processing methods.

Following the extraction of the basic elements, the image is present in a form represented symbolically by a set of defined basic elements.

In each case associated basic elements are combined to form a coherent structure, to be specific a system of polygons.

Each basic element is assigned information about the surroundings, that is to say information about other basic elements which are adjacent to the basic element. The information about the surroundings characterizes the basic element and permits its identification within the set of all basic elements.

A basic element 301 of this type, with information 302 about the surroundings, which is assigned to the basic element, is in each case represented in FIG. 3a to FIG. 3c.

The information about the surroundings is formed by a set of further basic elements and their geometric arrangement relative to one another and to the basic element 301 itself.

The information about the surroundings which is assigned to the basic element 301 is formed in such a way that it is as invariant as possible with respect to errors which can occur when the map 101 is being constructed by the robot 201.

It has transpired that a pair of orthogonal basic elements in the form of paths are particularly well suited to the method. In this case, it should be noted that the exact orthogonality of the basic elements does not matter, but that a tolerance can readily be tolerated.

The information about the surroundings which is assigned to the basic element 301 is the distance between the points of intersection of basic elements that are aligned parallel to one another with the basic element 301, designated by DX in FIG. 3a

Furthermore, information about the surroundings which is stored is a first angle W1 which is formed by an angle of intersection of a first further basic element 303, which has a length L1, with the basic element 301.

Furthermore, a second angle W2, which designates an angle of intersection of the second further basic element 304 with the basic element 301, as well as the length L2 of the second further basic element 303, is assigned to the basic element 301 as information about the surroundings.

Further information assigned to the basic element 301 about the surroundings is a statement relating to the starting point and/or the end point and therefore also an orientation in each case of the first and/or second basic element 303, 304.

The information about the surroundings is stored as a list, which is assigned to the basic element 301. The list is sorted in a predefinable manner.

The pair of orthogonal basic elements, as illustrated in FIG. 3a as information about the surroundings, forms one surroundings information type.

The individual elements described above, which are assigned to the basic element 301 as information about the surroundings, form surroundings information features which are in each case assigned to the surroundings information type.

A second surroundings information type is a further basic element 310 which is parallel to the basic element 301 (cf. FIG. 3b).

Again, exact parallelism of the further basic element 310 and the basic element 301 is not required. The surroundings information features that are stored are a distance Dy between the basic element 301 and the further, parallel basic element 303, and also a third angle W3 between the exact parallels 311 of the first basic element 301, displaced by the distance Dy, and the actual position of the further, parallel basic element 310.

FIG. 3c shows a further surroundings information type in the form of points 320, 321, which designate points belonging to a structure 322 of lines which lie closest to the basic element 301.

In this case, a distance between these points 320, 321 (designated Dz) and the shortest distances N1, N2 between the points 320, 321 and the basic element 301 are stored as surroundings information features.

In the predefined, stored map 101, in each case information about the surroundings is assigned to the basic elements in the same way. Thus, the stored map 101 has a set of basic elements each having information about the surroundings assigned to the basic elements in the form of surroundings information types with the surroundings information features assigned to the surroundings information types.

Therefore, in a second step 502, the information about the surroundings is in each case assigned to the basic elements which are contained in the image area 111, and also the basic elements contained in the map 101.

For each basic element 301, in a further step 503, a value of the level of similarity is formed with all the further basic elements.

The level of similarity will be explained in more detail in the further text.

In this exemplary embodiment, it will be assumed that an overall value U of the information about the surroundings which is respectively assigned to the basic element 301 results in accordance with the following rule:

U=(OP, P, M),

where

OP designates the surroundings information features which is formed by pairs of further basic elements oriented perpendicular to each other,

OP designates the surroundings information features formed by parallel basic elements, and

M designates the surroundings information features of the point-like surroundings information types.

The surrounding information features are present in the form of sorted lists.

Let

v: U×U→

[symbol]

be a formal definition of a comparison function.

Using the comparison function v, a comparison value is calculated in relation to a pair of items of information about the surroundings each associated with two basic elements. The higher the comparison value is, the better the two surroundings information features of the basic elements agree with one another. To define the comparison function v, the following three functions vOP, vP, vMP are defined:

vOP: OP×OP→

[symbol]

vP P×P→

[symbol]

vMP: MP×MP→

[symbol]

where vOP describes a comparison value for surroundings information features of the surroundings information type with perpendicular further basic elements and, in an analogous way, vP describes a comparison value of surroundings information features of the surroundings information type with parallel basic elements. vMP describes a comparison value which determines surroundings information features of the surroundings information type with points as surroundings information features.

The comparison function v is defined as the weighted sum of the functions vOP, vP and vMP in accordance with the following rule.

v(U1, U2)=aOP*vOP(OP1, OP2)+aP*vP(P1, P2)+aMP ** vMP(MP1, MP2).

The values aOP, aP and aMP in the numeric interval [0,1] are designated weighting values.

Using the weighting values aOP, aP and aMP, the differing significances of the individual surroundings information types with regard to the level of similarity are taken into account. It has transpired that the surroundings information type of the pairs of orthogonal further basic elements OP is more meaningful with regard to the level of similarity than the surroundings information type of the parallel further basic elements P, and the latter is in turn more meaningful than the surroundings information type with points as surroundings information features.

For each function vOP, vP, vMP, for each basic element and its surroundings information features, in each case a dynamic programming method is carried out, by which means an intermediate similarity value is formed.

This is carried out in each case for each function vOP, vP, vMP by using the following cost function Dᵢ, j:

$${D}_{i , j} = min \{ \begin{matrix}{D}_{i - 1 , j} + δ \\ {D}_{i - 1 , j} - 1 + μ , \\ {D}_{i , j - 1} + δ\end{matrix}$$

where

δ designates a predefinable cost value which occurs when a surroundings information feature from the recorded image area cannot be assigned to a surroundings information feature from the stored map 101,

$$\begin{matrix}- μ = \frac{δ}{λ} , with \\ - λ = {\prod }_{k = 1}^{n} ( max \{ 0 , 1 - \frac{\vert {a}_{k , i} - {a}_{k , j} \vert}{{Max Err}_{k}} \} ) .\end{matrix}$$

where

k is an index which uniquely designates each surroundings information type which is taken into account in the context of the dynamic programming,

n designates the number of basic elements taken into account,

a_{k,i} and a_{k,j} designate the individual surroundings information features which are stored in the sorted list of the respective surroundings information types, a_{k,i} designating a surroundings information feature of a basic element from the image area 111, and a_{k,j} designating a surroundings information feature of a basic element from the map 101,

MaxErrₖ designates a predefinable value that is specific to each surroundings information type.

The cost value δ has to be determined empirically in such a way that, in the given application

2·δ>μ, if the assignment is correct, and

μ>2·δ, if the assignment is not correct.

The following relationship between the individual weighting values has proven to be advantageous:

aOP:aP:aMP=3:2:1.

The result of the comparison function v forms a value of the level of similarity with which the similarity between the first structure in the image area 111 and the second area in the map 101 is described (step 503).

In a further step 504, from the first structure and the second structure, that pair of basic elements which has the highest value of the intermediate similarity value and is therefore most similar to each other is selected.

For the selected basic elements, a canonical coordinate system is formed in the respective map, its x-axis being formed by the respective basic element (step 505).

In a further step 506, a projection level is then determined. The projection level determines, for the selected basic elements, what amount of translation or rotation is necessary in order to project the coordinate system for the basic element from the first structure in each case onto a coordinate system of a basic element from a further structure.

In step 506, it is obviously therefore determined in each case to what extent the coordinate system of the selected basic element from the first structure has to be displaced or “rotated” in order to “fit” the coordinate system of the selected basic element from a further structure in each case.

In the predefined map, that area is selected whose projection level and/or whose level of similarity is a minimum as compared with the coordinate system for the basic element from the first structure.

Starting from the selected basic element, further basic elements are selected in pairs (that is to say in each case one basic element from the first structure and one basic element from the second structure) whose values of the level of similarity are greater than a predefinable threshold value.

It is then known to the robot 201 where it is located within the map 101.

Thus, in a step 507, that area in the predefined map 101 in which the robot 201 is located is determined.

After step 507 has been completed, the first selected basic element and the associated structure are present in the image area 1il, and the corresponding selected basic element and the associated second structure are present in the selected area of the map 101.

In a further step 508, the position of the selected basic element and the position of the associated second structure in the selected area from the map 101 are changed or corrected by using the positions of the corresponding elements from the first structure in the image area 111 (cf. FIG. 6).

In FIG. 6, a selected basic element 601 and an associated second structure 602 in a map, and also a corresponding selected basic element 611 and an associated first structure 612, which was determined in the image area and in likewise entered into the map, is illustrated in the map.

The first structure 612 and the second structure 602 are in each case represented by a system of polygons in FIG. 6, in each case a first polygon (starting polygon) 601, 611 of the system of polygons being the selected basic element.

The basic element 611, 601 of the first structure 612 and of the second structure 602 is in each case described by a first orientation 614 and a second orientation 604 and a first point 613 and a second point 603, respectively.

The first 614 and second 604 orientation are determined in such a way that a first direction 614 and a second direction 604 are determined by using a starting point 615, 605 and an end point 616, 606 of the first and second basic element 611, 601. The first 613 and second 603 point is in each case the center of the basic element.

It should be noted that a basic element could be described by using any other desired geometric representations which describe the orientation of the basic element uniquely, for example a starting point and an end point of the polygon or a starting point and a direction of the polygon.

A new, corrected position or direction 624 of the basic element 621 (starting polygon) is determined by an average of the first 614 and the second 604 direction being determined. A new, corrected point 623 is determined in such a way that a center of a path which joins the first point 613 and the second point 603 is determined.

The following is therefore true of the new, corrected position n′ of the basic element 621:

$$\begin{matrix}{n}^{′} = ( {x}^{′} , {y}^{′} , {β}^{′} ) = ( \frac{{x}_{k} + {x}_{l}}{2} , \frac{{y}_{k} + {y}_{l}}{2} , m ( {β}_{k} , {β}_{l} ) ) \\ and & ( 1 ) \\ m ( {β}_{k} , {β}_{l} ) = 0.5 * arctan ( ( \begin{matrix}cos {β}_{k} \\ sin {β}_{k}\end{matrix} ) ( \begin{matrix}cos {β}_{l} \\ sin {β}_{l}\end{matrix} ) ) & ( 2 )\end{matrix}$$

where

k, l is an index for a basic element from the first or the second structure

x, y is a coordinate in a Cartesian coordinate system

β is the directional angle of a basic element in the Cartesian coordinate system

′ is an index for the new corrected position

arctan ( . . . ) is an angular function.

The new corrected positions 625 of the other elements of the corrected structure are determined in such a way that the energy which is needed for the changes of the positions 625 of the other elements is a minimum.

As can be seen, this procedure may be illustrated by a structure being described by means of a frameframework 700 which is built up from nodes 701 and rods 702 connected to each other in an articulated manner at nodes 701 (FIG. 7). In each case, two interconnected rods 702 are coupled by springs 703.

A change in a position of a rod 702 leads to stressing of the springs 703 joined to the rod 702, some energy (spring energy) having to be expended for this stressing. In the event of a change in a position of a rod 702 (starting polygon), the positions of the other interconnected rods 702 are adjusted in such a way that the overall spring energy e which has to be applied for the stressing of all the springs 703 is a minimum.

This optimization task may be described as follows:

$$e = {\sum }_{( i , j ) ∈ N} ( \frac{{( {d}_{ij} - {\hat{d}}_{ij} )}^{2}}{{w}_{i , j}^{d}} + \frac{{( Δ {α}_{i , j} )}^{2}}{{w}_{i , j}^{α}} + \frac{{( Δ {α}_{j , i} )}^{2}}{{w}_{j , i}^{α}} ) -> min \qquad ( 3 )$$

in which the following are true:

$${Δα}_{i , j} = arctan ( \frac{( - Δ x sin {γ}_{i} + Δ y cos {γ}_{i} ) }{( Δ x cos {γ}_{i} + Δ y sin {γ}_{i} )} ) \qquad ( 4 )$$

Δx=xᵢ−xⱼ (5)

Δy=yᵢ−yⱼ (6)

γᵢ=βᵢ−α_{i,j} (7)

γⱼ=βⱼ−α_{j,i} (8)

where

i, j is an index for a node 701 from the first or the second structure

d, \hat{d} is the new distance or original distance between two nodes 701 in the Cartesian coordinate system

w are weights

α is a directional angle of a connection between two nodes 701

γ is an angle in the Cartesian coordinate system

Δ . . . is a change.

The optimization method used is the method of the steepest drop, which is described in [2].

In this way, the new, corrected positions of the other elements of the structure 625 are determined. The new, corrected structure 625 is entered into the map instead of the second structure 602 and is stored.

The method described has the advantage that the position of the robot in the space or in the map is determined by the method and, at the same time, areas from the map are changed or corrected.

Thus, during a movement of the robot in the space, the map is corrected continuously during the movement of the robot.

In the further text, some alternatives to the exemplary embodiment described above will be indicated:

To solve the optimization task described in step 508 (cf. Formula), the method of conjugate gradients or a quasi-Newton method can also be used.

Elongate elements, in particular long paths or polygons, belonging to a structure can be subdivided into a plurality of part elements, part paths or part polygons. The number of rods is therefore increased in accordance with the subdivision. However, the Formulas (1)-(8) are to be applied in the same way.

In the course of this document, the following publications have been cited:

[1] O. Karch and H. Noltemeier, Autonome Mobile Systeme [Autonomous Mobile Systems] 1996, G. Schmidt and F. Freyberger, (Eds.), Zum Lokalisationsproblem für Roboter, [On the Localization Problem for Robots], Springer Verlag, ISBN 3-54061-751-5, pp. 128-137, 1996.

[2] W. H. Press, et al., Numerical Recipes in C, The Art of Scientific Computing, Cambridge University Press, Cambridge, New York, Melbourne, pp. 317-324, 1988.

1. A method for the computer-assisted processing of a structure comprising a first element and a second element belonging together,
in which a third position of the first element is determined by using a first position of the first element and a changed second position of the first element;
in which, on processing the structure, at least one fourth position of the second element of the structure is changed by using the third position of the first element.

2. The method as claimed in claim 1, in which an element is described by at least one point and a line of predefinable shape.

3. The method as claimed in claim 2, in which a position of an element is described by the point of the element and an orientation of the line of the element.

4. The method as claimed in claim 3, in which the third position of the first element is determined by an angle between a first orientation of the first position of the first element and a second orientation of the second position of the first element being determined, the angle being averaged and a direction of the averaged angle describing a third orientation of the third position of the first element.

5. The method as claimed in one of claims 1 to 4, in which the fourth position of the second element is changed in such a way that the energy which has to be expended for a change in at least one position of the first element and one position of the second element is minimized.

6. The method as claimed in one of claims 1 to 5, in which the processed structure is entered in a map.

7. The method as claimed in claim 6, in which the map is recorded by using a recording means.

8. The method as claimed in claim 7, in which the map is recorded at least with one of the following recording means:
with an acoustic sensor;
with an optical sensor, in particular a camera.

9. The method as claimed in claim 5, in which the map is used for planning the travel path of a mobile autonomous device.

10. The method as claimed in one of claims 1 to 8, in which a mobile device is monitored and/or controlled by using the changed structure.

11. The method as claimed in claim 10, in which a robot is used as the mobile device.

12. An arrangement for the computer-assisted processing of a structure comprising a first element and a second element which belong together, having a processor which is set up in such a way that the following steps can be carried out
a third position of the first element is determined by using a first position of the first element and a changed second position of the first element;
on processing the structure, at least one fourth position of the second element of the structure is changed by using the third position of the first element.
